(19) United States
(12) Patent Application Publication
(10) Pub. No.: US 2025/0029914 A1
(43) Pub. Date: Jan. 23, 2025

(54) SEMICONDUCTOR PACKAGE WITH BACKSIDE POWER DELIVERY NETWORK LAYER

(71) Applicant: SAMSUNG ELECTRONICS CO., LTD., SUWON-SI (KR)

(72) Inventors: Hyunsoo CHUNG, Suwon-si (KR); Kwang-Soo KIM, Suwon-si (KR); Jinchan AHN, Suwon-si (KR)

(21) Appl. No.: 18/430,241

(22) Filed: Feb. 1, 2024

(30) Foreign Application Priority Data
Jul. 20, 2023 (KR) 10-2023-0094555

(51) Int. Cl. H01L 23/498; H01L 23/00; H01L 25/065; H10B 80/00

(52) U.S. Cl. CPC H01L 23/49838; H01L 23/49816; H01L 24/08; H01L 24/32; H01L 25/0652; H01L 2224/08146; H01L 2224/08155; H01L 2224/32146; H01L 2224/32157; H01L 2924/01029; H01L 2924/1434; H01L 2924/15311; H01L 2924/182; H10B 80/00

(57) ABSTRACT

A semiconductor package includes a logic die that includes a backside power delivery network layer, an interposer die disposed on the logic die, a plurality of memory dies stacked on the interposer die, and a mold layer that covers the interposer die and the memory dies. Each of the logic die and the interposer die has a first width.

### CROSS-REFERENCE TO RELATED APPLICATIONS

This U.S. non-provisional patent application claims priority under 35 U.S.C. § 119 from Korean Patent Application No. 10-2023-0094555, filed on Jul. 20, 2023 in the Korean Intellectual Property Office, the contents of which are herein incorporated by reference in their entirety.

### TECHNICAL FIELD

The present disclosure relates to a semiconductor package, and in particular, to a stack-type semiconductor package including a backside power delivery network (BSPDN) layer.

### DISCUSSION OF THE RELATED ART

A semiconductor package is configured so that an integrated-circuit chip can be easily used as a part of an electronic product. Conventionally, a semiconductor package includes a printed circuit board (PCB) and a semiconductor chip die that is mounted on the PCB and is electrically connected to the PCB using bonding wires or bumps. Many studies are being conducted to improve reliability and durability of the semiconductor package.

### SUMMARY

An embodiment of the inventive concept provides a semiconductor package with increased heat-dissipation and reliability characteristics.

An embodiment of the inventive concept provides a method of increasing a yield in a process of fabricating a semiconductor package.

According to an embodiment of the inventive concept, a semiconductor package includes a logic die that includes a backside power delivery network layer, an interposer die disposed on the logic die, a plurality of memory dies stacked on the interposer die, and a mold layer that covers the interposer die and the memory dies. Each of the logic die and the interposer die has a first width.

According to an embodiment of the inventive concept, a semiconductor package includes a logic die, an interposer die disposed on the logic die, a plurality of memory dies stacked on the interposer die, a mold layer that covers the interposer die and the memory dies, and a supporting substrate disposed on the memory dies and the mold layer. The logic die includes a backside power delivery network layer, a first substrate disposed on the backside power delivery network layer, a frontside interconnection layer disposed on the first substrate, and a first penetration via that penetrates the first substrate and is connected to the backside power delivery network layer. Each of the memory dies includes second penetration vias, and the interposer die includes third penetration vias that connect the logic die to the memory dies. The backside power delivery network layer has a first thickness, and the frontside interconnection layer has a second thickness that is less than the first thickness. Each of the memory dies has a third thickness, a sum of thicknesses of the logic and interposer dies is greater than the third thickness, and a diameter of the third penetration via is greater than a diameter of the second penetration via. A number of the third penetration vias is equal to or greater than a number of the second penetration via. The mold layer includes an oxide material, and the supporting substrate includes silicon. Each of the logic and interposer dies has a first width, and the interposer die has a higher thermal conductivity than the logic and memory dies.

According to an embodiment of the inventive concept, a semiconductor package includes a package substrate, an interposer substrate disposed on the package substrate, and a first semiconductor chip and a second semiconductor chip disposed on the interposer substrate and arranged side by side in a first direction. The second semiconductor chip includes a logic die that includes a backside power delivery network layer, an interposer die disposed on the logic die, a plurality of memory dies stacked on the interposer die, and a mold layer that covers the interposer die and the memory dies. The mold layer includes an oxide material, and the interposer die has a higher thermal conductivity than the logic memory dies.

### BRIEF DESCRIPTION OF THE DRAWINGS

FIG. 1A is a sectional view of a semiconductor package according to an embodiment of the inventive concept.

FIG. 1B is an enlarged sectional view of a portion ‘P1’ of FIG. 1A.

FIG. 1C is an enlarged sectional view of a portion ‘P2’ of FIG. 1A.

FIG. 1D is an enlarged sectional view of a portion ‘P3’ of FIG. 1A.

FIG. 2 is a sectional view of a semiconductor package according to an embodiment of the inventive concept.

FIG. 3 is a sectional view of a semiconductor package according to an embodiment of the inventive concept.

FIGS. 4A to 4H are sectional views that illustrate a process of fabricating a semiconductor package of FIG. 1A.

FIG. 5 is a sectional view of a semiconductor package according to an embodiment of the inventive concept.

### DETAILED DESCRIPTION

Embodiments of the inventive concepts will now be described more fully with reference to the accompanying drawings, in which embodiments are shown.

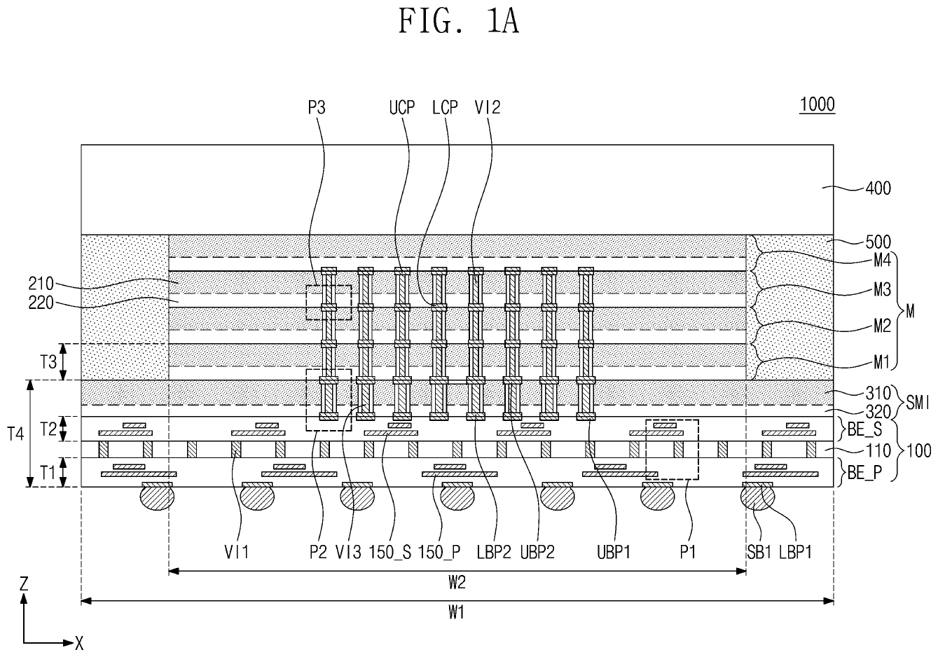

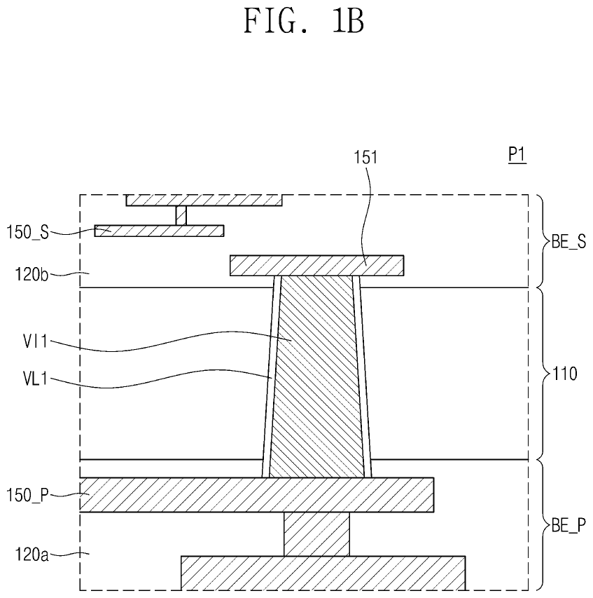

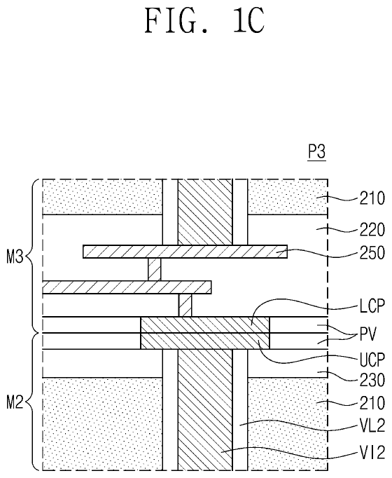

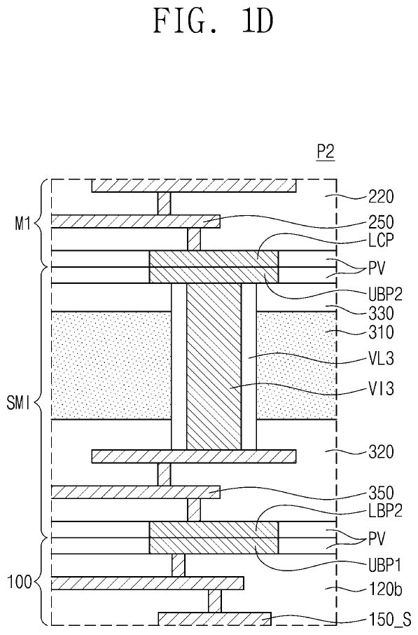

FIG. 1A is a sectional view of a semiconductor package according to an embodiment of the inventive concept. FIG. 1B is an enlarged sectional view of a portion ‘P1’ of FIG. 1A. FIG. 1C is an enlarged sectional view of a portion ‘P2’ of FIG. 1A. FIG. 1D is an enlarged sectional view of a portion ‘P3’ of FIG. 1A.

Referring to FIGS. 1A to 1D, a semiconductor package 1000 according to an embodiment of the inventive concept includes a logic die 100, an interposer die SMI disposed on the logic die 100, a plurality of memory dies M stacked on the interposer die SMI, a mold layer 500, and a supporting substrate 400. The memory dies M include a first memory die M1, a second memory die M2, a third memory die M3, and a fourth memory die M4. The logic die 100 and the interposer die SMI have a same width, such as a first width W1.

The logic die 100 includes a backside power delivery network layer BE_P, a first substrate 110 disposed on the backside power delivery network layer BE_P, and a frontside interconnection layer BE_S disposed on the first substrate 110. The backside power delivery network layer BE_P has a first thickness T1, and the frontside interconnection layer BE_S has a second thickness T2 that is equal to or different from the first thickness T1. In an embodiment, the first thickness T1 is greater than the second thickness T2.

As shown in FIG. 1B, in an embodiment, the backside power delivery network layer BE_P includes a first interlayer insulating layer 120a and a first power line 150_P. In addition, the first substrate 110 includes a transistor with source/drain patterns and a gate electrode. Lower metal layers are additionally disposed below the first interlayer insulating layer 120a. The frontside interconnection layer BE_S includes a second interlayer insulating layer 120b, a signal line 150_S, and a second power line 151. The first power line 150_P is thicker than the signal line 150_S. A width of the first power line 150_P is greater than a width of the signal line 150_S.

The first substrate 110 is a wafer-level semiconductor substrate that is formed of a semiconductor material, such as silicon (Si). For example, the first substrate 110 is one of a single-crystalline semiconductor substrate or a silicon-on-insulator (SOI) substrate. A first penetration via VI1 that is used to electrically connect the power lines 150_P and 151 to each other penetrates the first substrate 110, a portion of the second interlayer insulating layer 120b, and a portion of the first interlayer insulating layer 120a. Thus, a voltage can be applied from the backside power delivery network layer BE_P to the second power line 151 in the second interlayer insulating layer 120b through the first penetration via VI1. A first penetration insulating layer VL1 is interposed between the first penetration via VI1 and the first substrate 110. The first penetration via VI1 is formed of or includes at least one metal, such as aluminum, copper, tungsten, ruthenium, molybdenum, or cobalt. The first penetration insulating layer VL1 is formed of or includes at least one silicon-based insulating material, such as silicon oxide, silicon nitride, or silicon oxynitride). Since the backside power delivery network layer BE_P is disposed in the logic die 100, an integration density of the semiconductor package 1000 can be increased.

Referring to FIGS. 1A and 1C, in an embodiment, each of the first to fourth memory dies M1 to M4 includes a second substrate 210, a third interlayer insulating layer 220, and a fourth interlayer insulating layer 230. The second substrate 210 includes a transistor, and the third interlayer insulating layer 220 includes first internal interconnection lines 250. The second substrate 210 is a wafer-level semiconductor substrate that is formed of a semiconductor material, such as silicon (Si). For example, the second substrate 210 is one of a single-crystalline semiconductor substrate or a silicon-on-insulator (SOI) substrate. A second penetration via VI2 is disposed in each of the first to third memory dies M that penetrates the second substrate 210, the fourth interlayer insulating layer 230, and a portion of the third interlayer insulating layer 220. A second penetration insulating layer VL2 is interposed between the second penetration via VI2 and the second substrate 210. The second penetration via VI2 is formed of or includes at least one metal, such as copper, aluminum, or tungsten. The second penetration insulating layer VL2 is formed of or includes at least one of silicon oxide, silicon nitride, or silicon oxynitride, and may have a single- or multi-layered structure. The second penetration insulating layer VL2 includes an air gap region. The fourth memory die M4 does not include the penetration via.

Referring to FIGS. 1A and 1D, in an embodiment, the interposer die SMI includes a third substrate 310, a fifth interlayer insulating layer 320, and a sixth interlayer insulating layer 330. The third substrate 310 does not include a transistor. The fifth interlayer insulating layer 320 includes second internal interconnection lines 350. The third substrate 310 is a power semiconductor substrate that contains silicon carbide (SiC). Since silicon carbide has a break-down voltage that is ten or more times greater than that of silicon (Si), silicon carbide can be used to realize an electric component with a high breakdown voltage, and thus, reduce power loss. In addition, since silicon carbide has a band gap that is about three times greater than that of silicon, the interposer die SMI that contains silicon carbide can be operated at a higher temperature than a silicon-containing substrate. Thus, the interposer die SMI has a heat-resistant property and a thermal conductivity that are superior or higher than those of the silicon substrates of the logic and memory dies 100 and M. Thus, heat, which is generated in the logic die 100, can be effectively dissipated through the interposer die SMI, and the semiconductor package 1000 with lowered thermal resistance and increased reliability can be realized.

A third penetration via VI3 is disposed in the interposer die SMI that penetrates the third substrate 310, the sixth interlayer insulating layer 330, and a portion of the fifth interlayer insulating layer 320. A third penetration insulating layer VL3 is interposed between the third penetration via VI3 and the third substrate 310. The third penetration via VI3 electrically connects the logic die 100 to the memory dies M. The third penetration via VI3 is formed of or includes at least one metal, such as copper, aluminum, or tungsten. The third penetration insulating layer VL3 is formed of or includes at least one of silicon oxide, silicon nitride, or silicon oxynitride, and may have a single- or multi-layered structure. The third penetration insulating layer VL3 includes an air gap region. A diameter of the third penetration via VI3 is greater than a diameter of the second penetration via VI2. The number of the third penetration vias VI3 is equal to or greater than the number of the second penetration vias VI2.

The first to sixth interlayer insulating layers 120a, 120b, 220, 230, 320, and 330 are formed of or include at least one of silicon oxide, silicon nitride, silicon oxynitride, or porous insulating materials, and may have a single- or multi-layered structure. The first to sixth interlayer insulating layers 120a, 120b, 220, 230, 320, and 330 are each covered with a passivation layer PV. The passivation layers PV are formed of or include at least one of silicon oxide, silicon nitride, or SiCN, and may have a single- or multi-layered structure.

The internal interconnection lines 250 and 350, the signal line 150_S, and the power lines 150_P and 151 are formed of or include at least one of copper, aluminum, tungsten, titanium, titanium nitride, tantalum, tantalum nitride, ruthenium, or iridium, and may have a single- or multi-layered structure.

First upper conductive pads UBP1 are disposed on a top surface of the logic die 100. First lower conductive pads LBP1 are disposed on a bottom surface of the logic die 100. Second upper conductive pads UBP2 are disposed on a top surface of the interposer die SMI. Second lower conductive pads LBP2 are disposed on a bottom surface of the interposer die SMI. Upper chip pads UCP are disposed on top surfaces of the first to third memory dies M. In an embodiment, the upper chip pad UCP are not provided in the fourth memory die M4. Lower chip pads LCP are disposed on bottom surfaces of the first to fourth memory dies M1 to M4. The upper conductive pads UBP1 and UBP2, the lower conductive pads LBP1 and LBP2, the upper chip pads UCP, and the lower chip pads LCP are formed of or include at least one metal, such as copper (Cu), gold (Au), nickel (Ni), tin (Sn), silver (Ag), tungsten (W), or aluminum (Al)). First outer connection members SB1 are bonded to the first lower conductive pads LBP1. The first outer connection members SB1 include at least one of copper bumps, copper pillars, or solder balls.

In an embodiment, as shown in FIG. 1C, the upper chip pads UCP of the second memory die M2 are in direct contact with the corresponding lower chip pads LCP of the third memory die M3. Referring back to FIGS. 1 and 1C, the upper chip pads UCP of the first to fourth memory dies M1 to M4 are in direct contact with the corresponding lower chip pads LCP. The passivation layers PV of the first to fourth memory dies M1 to M4 are in direct contact with each other. The upper chip pads UCP and the lower chip pads LCP are formed of a same material. The upper chip pad UCP and the lower chip pad LCP, which are in contact with each other, are bonded to each other to form a single integrated object. Thus, there might be no interface between the upper chip pad UCP and the lower chip pad LCP.

Referring to FIG. 1D, in an embodiment, the first upper conductive pads UBP1 of the logic die 100 are in direct contact with the corresponding second lower conductive pads LBP2 of the interposer die SMI, respectively. The passivation layer PV of the logic die 100 is in direct contact with the passivation layer PV of the interposer die SMI. The first upper conductive pads UBP1 and the second lower conductive pads LBP2 are formed of a same material. The first upper conductive pad UBP1 and the second lower conductive pad LBP2, which are in contact with each other, are bonded to each other to form a single integrated object. Thus, there might be no interface between the first upper conductive pad UBP1 and the second lower conductive pad LBP2.

The second upper conductive pads UBP2 of the interposer die SMI are in direct contact with the corresponding lower chip pads LCP of the first memory die M1. The passivation layer PV of the interposer die SMI is in direct contact with the passivation layer PV of the first memory die M1. The second upper conductive pads UBP2 and the lower chip pads LCP are formed of a same material. The second upper conductive pad UBP2 and the lower chip pad LCP, which are in contact with each other, are bonded to each other to form a single integrated object. Thus, there might be no interface between the second upper conductive pad UBP2 and the lower chip pad LCP.

The mold layer 500 covers the interposer die SMI and the memory dies M. The mold layer 500 is formed of or includes an oxide material. For example, the mold layer 500 is formed of or includes an inorganic insulating material, such as silicon oxide.

The supporting substrate 400 covers the memory dies M and the mold layer 500. The supporting substrate 400 is formed of or includes silicon. The supporting substrate 400 is a reinforcing element that prevents warpage in the semiconductor package 1000, or spreads heat for heat dissipation. In addition, the supporting substrate 400 may include a substrate and an interlayer insulating layer. However, embodiments of the inventive concept are not necessarily limited thereto, and in some embodiment, the semiconductor package is provided without the supporting substrate 400. In an embodiment, a silicon oxide layer is interposed between the supporting substrate 400 and the second substrate 210 of the fourth memory die M4.

The logic die 100 is a base die that includes a semiconductor device. In some embodiments, the logic die 100 may be referred to as an interface die, a logic die, or a master die. The die may be referred to as a chip. The logic die 100 is an interface circuit between the memory dies M and an external controller. The logic die 100 is configured to receive commands, data, and/or signals that are transmitted from the external controller, and to transmit the received commands, data, and/or signals, to the memory dies M. The logic die 100 is, for example, a chip with a logic circuit.

The first to fourth memory dies M1 to M4 are sequentially stacked. The first to fourth memory dies M1 to M4 are memory chips of the same type. The memory chip may be, for example, one of a DRAM, a NAND Flash memory, an SRAM, an MRAM, a PRAM, or an RRAM chip. Each of the first to fourth memory dies M1 to M4 has a second width W2 in a first direction X and has a third thickness T3. The first width W1 of the logic die 100 and the interposer die SMI is greater than the second width W2 of the memory dies M. A sum of thicknesses of the logic die 100 and the interposer die SMI is a fourth thickness T4, which is greater than the third thickness T3.

FIG. 1 illustrates a structure in which one logic circuit chip and four memory chips are stacked, but the number of logic circuit chips and memory chips are not necessarily limited to this example and can change in other embodiments. In some embodiments, the semiconductor package includes eight or more stacked memory chips. The semiconductor package 1000 has a structure of a high bandwidth memory (HBM) chip.

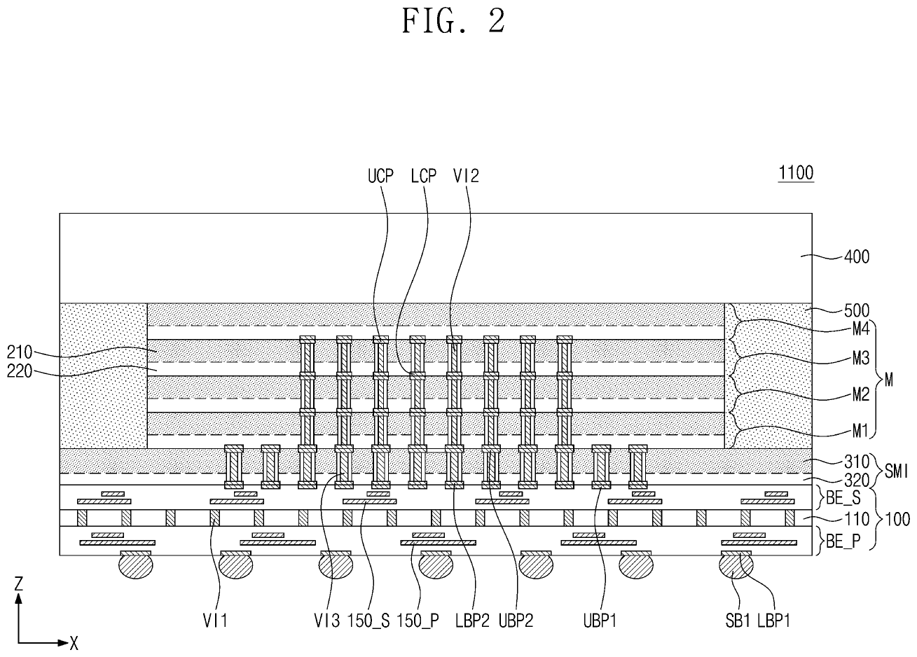

FIG. 2 is a sectional view of a semiconductor package according to an embodiment of the inventive concept.

Referring to FIG. 2, in an embodiment, a semiconductor package 1100 has a structure in which the number of the third penetration vias VI3 is greater than the number of the second penetration vias VI2 of FIG. 1. Increasing the number of the third penetration vias VI3 of the interposer die SMI increases the heat-dissipation efficiency of the logic die 100. For example, heat-dissipation characteristics of the semiconductor package can be increased. In addition, the semiconductor package can be configured to have the same or similar features as those of an embodiment of FIGS. 1A to 1D.

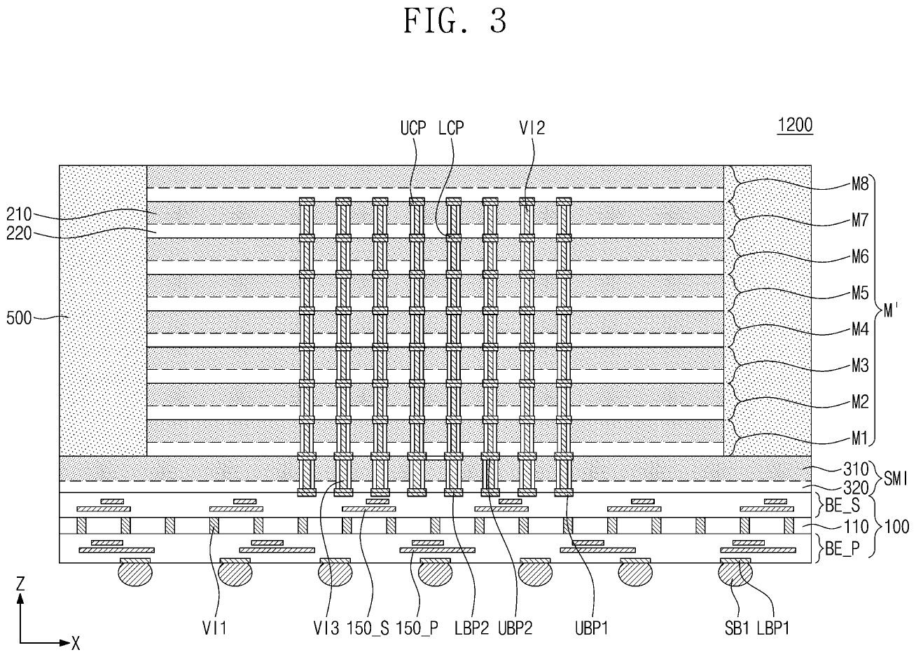

FIG. 3 is a sectional view of a semiconductor package according to an embodiment of the inventive concept.

Referring to FIG. 3, in an embodiment, a semiconductor package 1200 has a structure in which eight memory dies M′ are stacked on the interposer die SMI of FIG. 1A. The semiconductor package 1200 does not include the supporting substrate 400 of FIG. 1A that covers the mold layer 500 and the memory dies M. The semiconductor package 1200 has a structure in which the mold layer 500 and a top surface of an eighth memory die M8 are externally exposed. FIG. 3 illustrates an example in which the number of the third penetration vias VI3 in the interposer die SMI is equal to the number of the second penetration via VI2 in the memory dies M′, but embodiments of the inventive concept are not necessarily limited to this example. In some embodiments, the number of the third penetration vias VI3 is greater than the number of the second penetration via VI2. In addition, eight or more memory dies M′ may be stacked. In addition, the semiconductor package can be configured to have the same or similar features as those of an embodiment of FIGS. 1A to 1D.

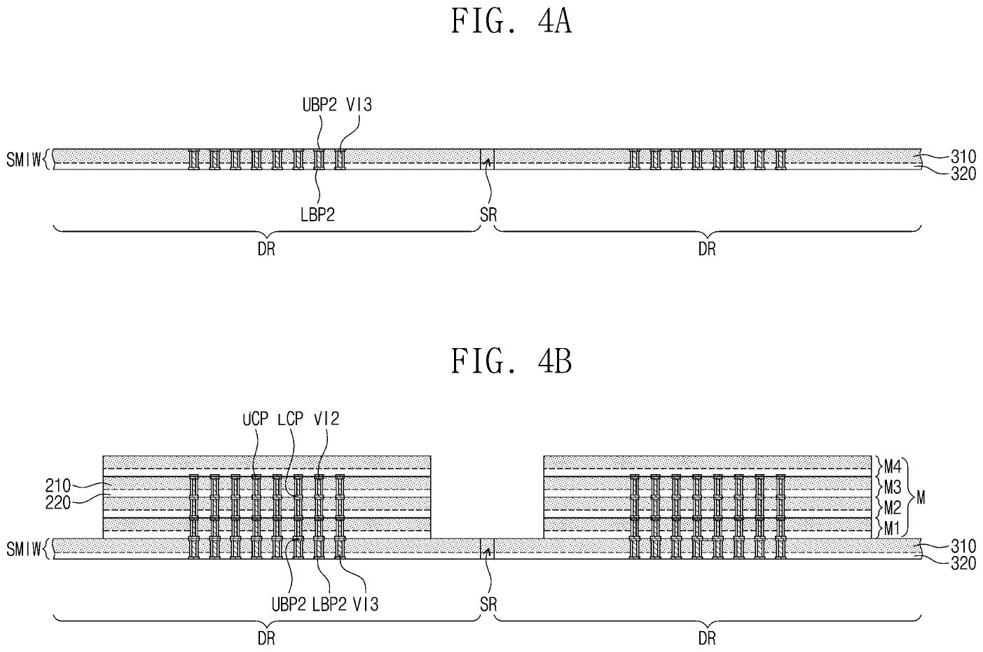

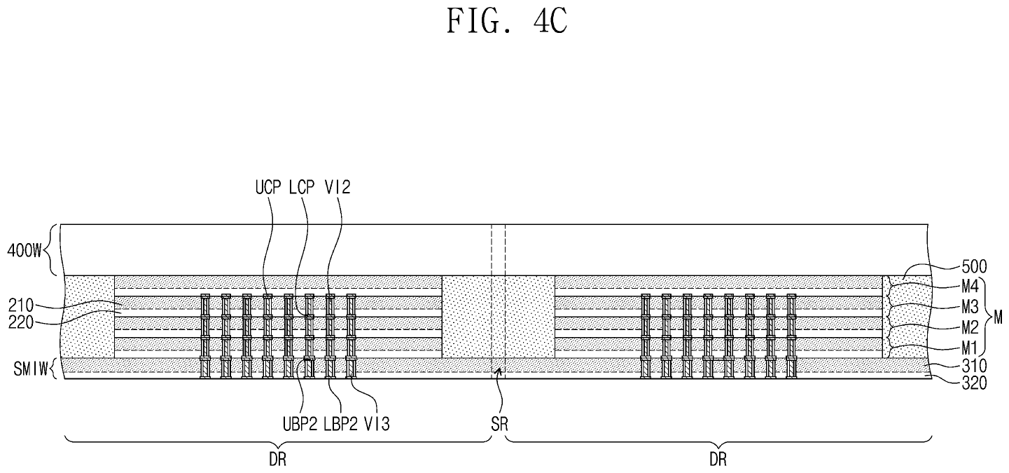

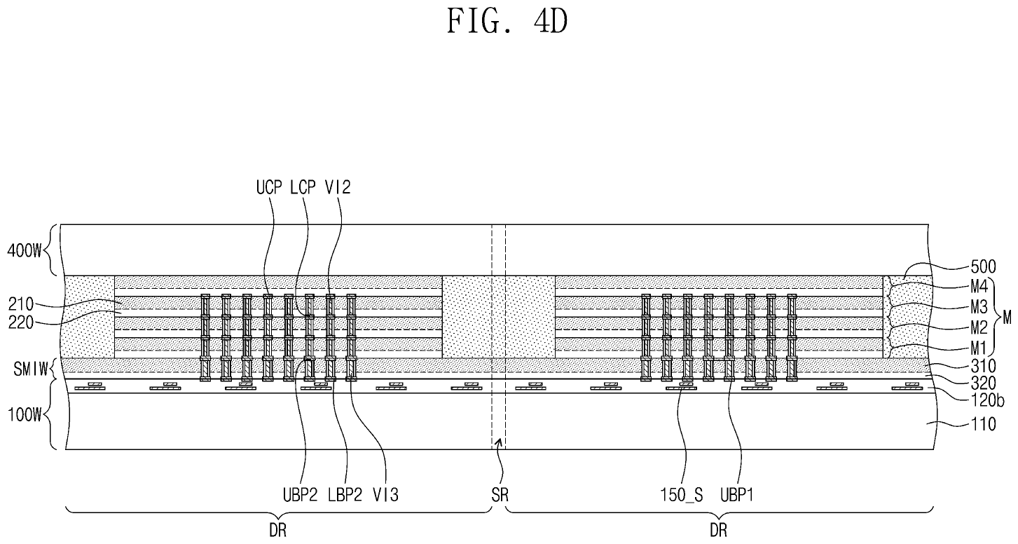

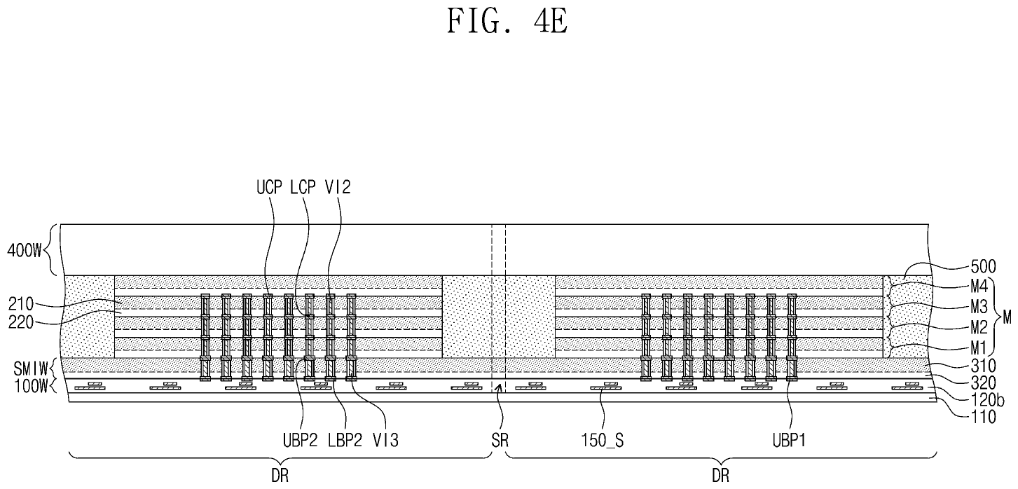

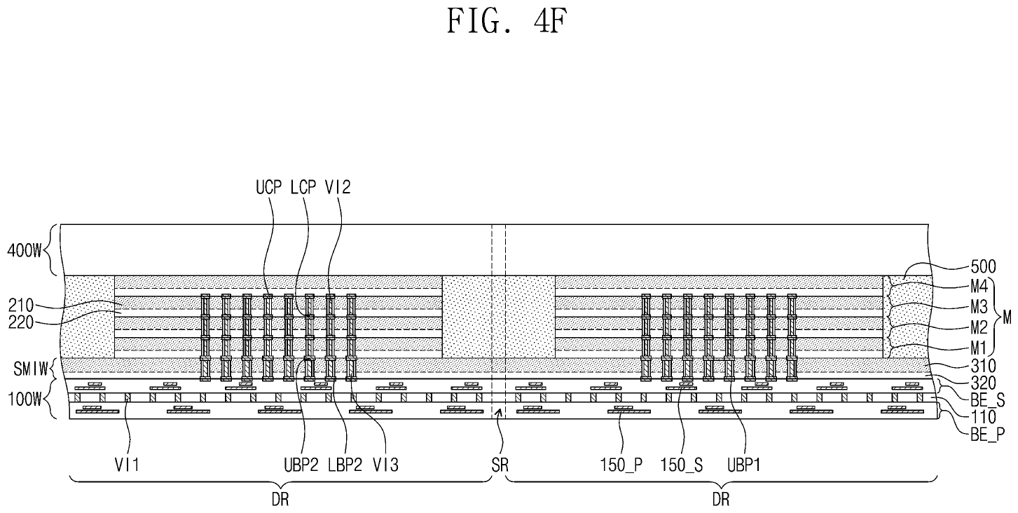

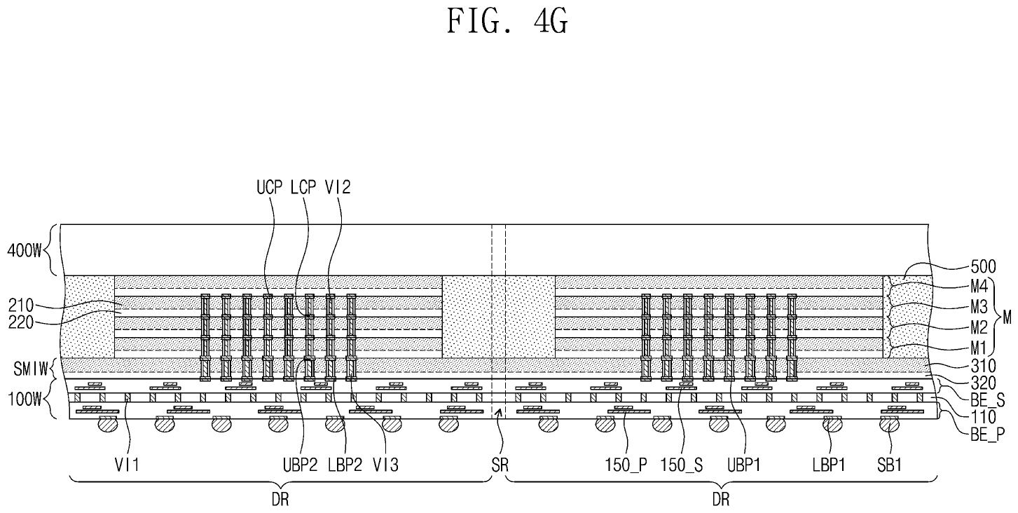

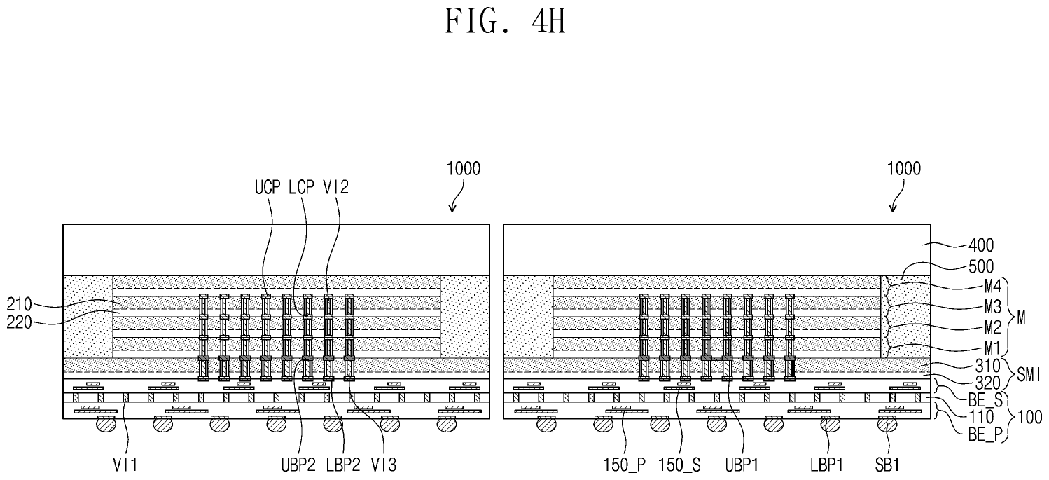

FIGS. 4A to 4H are sectional views that illustrate a process of fabricating a semiconductor package of FIG. 1A. For concise description, a previously described element may be identified by the same reference number without repeating an overlapping description thereof.

Referring to FIGS. 4A and 1D, in an embodiment, an interposer die wafer SMIW is prepared that includes a plurality of chip regions DR and a separation region SR therebetween. Each of the chip regions DR of the interposer die wafer SMIW has substantially the same structure as the interposer die SMI described with reference to FIGS. 1A to 1D. The separation region SR is a scribe lane region. The interposer die wafer SMIW includes the third substrate 310. The second internal interconnection lines 350 and an insulating layer, which covers the second internal interconnection lines 350 and is used as a portion of the fifth interlayer insulating layer 320, is formed on a bottom surface of the third substrate 310. The interposer die wafer SMIW does not include a transistor. The portion of the fifth interlayer insulating layer 320 and the third substrate 310 are etched to form a penetration hole, and the third penetration via VI3 and the third penetration insulating layer VL3 are formed in the penetration hole. The second internal interconnection lines 350, which are in contact with the third penetration via VI3, and the fifth interlayer insulating layer 320 are formed. The second lower conductive pads LBP2 and the passivation layer PV are formed on the fifth interlayer insulating layer 320.

A grinding or etch-back process is performed on a top surface of the third substrate 310 to remove a portion of the third substrate 310 and expose the third penetration insulating layer VL3. The top surface of the third substrate 310 is formed at a level that is lower than an end portion of the third penetration via VI3. For example, a thickness of the third substrate 310 is reduced by the grinding process. The third penetration via VI3 includes a protruding portion that is higher than the top surface of the third substrate 310. The sixth interlayer insulating layer 330 is formed on the top surface of the third substrate 310. A chemical-mechanical polishing (CMP) or etch-back process is performed to remove a portion of the sixth interlayer insulating layer 330 and a portion of the third penetration insulating layer VL3 and to expose the third penetration via VI3. The second upper conductive pads UBP2, the second lower conductive pads LBP2, and the passivation layer PV are formed on the sixth interlayer insulating layer 330.

Referring to FIGS. 4B, 1C, and 1D, in an embodiment, the memory dies M are prepared. The memory dies M include the first to fourth memory dies M1 to M4. Each of the first to fourth memory dies M1 to M4 includes the first internal interconnection lines 250, the third and fourth interlayer insulating layers 220 and 230, the second penetration via VI2, the second penetration insulating layer VL2, the upper chip pads UCP, the lower chip pads LCP, and the passivation layer PV that are formed on the second substrate 210 by a method described above with reference to FIG. 4A. Each of the memory dies M includes a transistor. A sawing process is performed such that the first to fourth memory dies M1 to M4 are formed to have a same size. The fourth memory die M4 is formed by performing the sawing process without forming the second penetration via VI2, the second penetration insulating layer VL2, and the upper chip pads UCP. The first to fourth memory dies M1 to M4 are formed to have the same thickness.

The first to fourth memory dies M1 to M4 are stacked on the chip regions DR of the interposer die wafer SMIW. The memory dies M are bonded to each other by one of a direct-bonding process or a hybrid copper bonding process. The second memory die M2 is disposed such that its active surface faces the first memory die M1. The second memory die M2 is placed such that the third interlayer insulating layer 220 is in contact with the second substrate 210 and the lower chip pads LCP are in contact with the upper chip pads UCP, and the second memory die M2 is directly bonded to the first memory die M1 by performing, for example, a thermo-compression process. The first and second memory dies M1 and M2 are directly bonded to each other by the upper chip pads UCP and the lower chip pads LCP to form an interface therebetween. The interface between the first and second memory dies M1 and M2 includes an inorganic insulating material, such as silicon oxide, that is present between the upper chip pads UCP and between the lower chip pads LCP. The above-described method is used to bond the second memory die M2 to the first memory die M1, bond the third memory die M3 to the second memory die M2, and bond the fourth memory die M4 to the third memory die M3.

The stacked memory dies M are bonded to the interposer die wafer SMIW by, for example, a thermo-compression process. In an embodiment, one of a direct-bonding process or a hybrid copper bonding process is performed to bond the first memory die M1 to the interposer die wafer SMIW. The first memory die M1 is disposed such that the active surface of the first memory die M1 faces the interposer die wafer SMIW. The first memory die M1 is placed such that the third interlayer insulating layer 220 is in contact with the third substrate 310 and the lower chip pads LCP are in contact with the second upper conductive pads UBP2, and the first memory die M1 is directly bonded to the interposer die wafer SMIW by, for example, a thermo-compression process. The interposer die wafer SMIW and the first memory die M1 are directly bonded to each other by the second upper conductive pads UBP2 and the lower chip pads LCP to form an interface therebetween. The interface between the interposer die wafer SMIW and the first memory die M1 includes an inorganic insulating material, such as silicon oxide, that is present between the second upper conductive pads UBP2 and between the lower chip pads LCP.

Referring to FIG. 4C, in an embodiment, a thermo-compression process is performed to bond the memory dies M to the interposer die wafer SMIW, and a casting process is performed to form the mold layer 500 that covers a top surface of the interposer die wafer SMIW and a side surface of the memory dies M. A supporting substrate wafer 400 W is bonded to the mold layer 500 and the memory dies M to cover them. The bonding of the supporting substrate wafer 400 W is performed by a direct-bonding process.

Referring to FIGS. 4D and 1D, in an embodiment, a logic die wafer 100 W that includes the first substrate 110, the signal line 150_S, and the second interlayer insulating layer 120b is prepared. The logic die wafer 100 W includes a transistor. As described above with reference to FIG. 4B, the interposer die wafer SMIW is bonded to the logic die wafer 100 W by one of a direct-bonding process or a hybrid copper bonding process. The interposer die wafer SMIW is placed such that the fifth interlayer insulating layer 320 is in contact with the first substrate 110 and the second lower conductive pads LBP2 are in contact with the first upper conductive pads UBP1, and the interposer die wafer SMIW is directly bonded to the logic die wafer 100 W by, for example, a thermo-compression process.

Referring to FIG. 4E, in an embodiment, a grinding or etch-back process is performed on a bottom surface of the logic die wafer 100 W to remove a portion of the logic die wafer 100 W and reduce a thickness of the logic die wafer 100 W.

Referring to FIGS. 4F and 1B, in an embodiment, a back-end-of-line (BEOL) process is performed that forms the first penetration via VI1, the first penetration insulating layer VL1, the first power line 150_P, and the first interlayer insulating layer 120a on the bottom surface of the logic die wafer 100 W, on which the grinding process was performed. Thus, the logic die wafer 100 W includes the backside power delivery network layer BE_P, the first substrate 110, and the frontside interconnection layer BE_S.

Referring to FIG. 4G, in an embodiment, the first lower conductive pads LBP1 and a passivation layer that covers them are formed on the first interlayer insulating layer 120a. The first outer connection members SB1 are bonded to the first lower conductive pads LBP1.

Referring to FIG. 4H, in an embodiment, a dicing process that uses, for example, a laser beam, is performed that removes the separation region SR, and as a result, a plurality of semiconductor packages 1000 are formed. Thus, the semiconductor packages 1000 of FIG. 1A can be formed.

In a method of fabricating a semiconductor package according to an embodiment of the inventive concept, the backside power delivery network layer BE_P is formed in a wafer-on-wafer (WoW) manner or by applying the WOW method, which can increase the productivity and yield of the fabrication process.

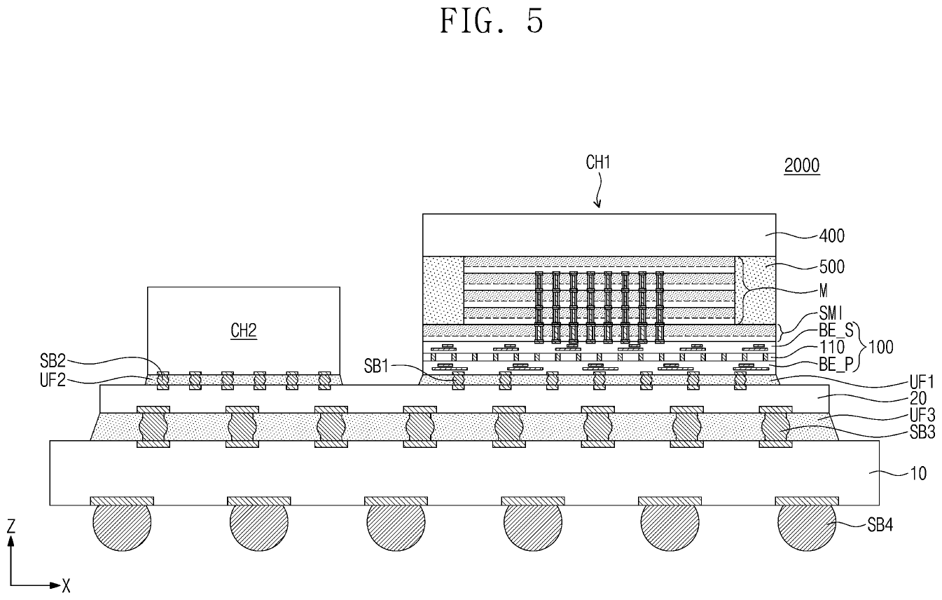

FIG. 5 is a sectional view of a semiconductor package according to an embodiment of the inventive concept.

In a semiconductor package 2000 according to an embodiment of the inventive concept, an interposer substrate 20 is disposed on a package substrate 10. The package substrate 10 may be, for example, a double-sided or multi-layered printed circuit board. The interposer substrate 20 is formed of or includes, for example, silicon. A first semiconductor chip CH1 and a second semiconductor chip CH2 are disposed next to each other in the first direction X on the interposer substrate 20. The interposer substrate 20 includes internal interconnection lines that connect the first semiconductor chip CH1 and the second semiconductor chip CH2 to each other. The first semiconductor chip CH1 may be an application specific integrated circuit (ASIC) chip or a system-on-chip. The first semiconductor chip CH1 may be referred to as a host or an application processor (AP). The first semiconductor chip CH1 is connected to the interposer substrate 20 through the first outer connection members SB1. The second semiconductor chip CH2 has the same or similar features as the semiconductor package 1000 described above with reference to FIGS. 1A to 4H. The second semiconductor chip CH2 is connected to the interposer substrate 20 by second outer connection members SB2. The interposer substrate 20 is bonded to the package substrate 10 by third outer connection members SB3. Fourth outer connection members SB4 are bonded to a bottom surface of the package substrate 10. The outer connection members SB1 to SB4 include at least one of copper bumps, copper pillars, or solder balls. Under-fill layers UF1 to UF3 respectively fill spaces between the first semiconductor chip CH1 and the interposer substrate 20, between the second semiconductor chip CH2 and the interposer substrate 20, and between the interposer substrate 20 and the package substrate 10. The under-fill layers UF1 to UF3 are formed by a dispensing process and a curing process. The under-fill layers UF1 to UF3 are formed of or include an epoxy resin and protect the outer connection members SB1 to SB3.

In a semiconductor package according to an embodiment of the inventive concept, by disposing a power delivery network on a bottom surface of a substrate, integration density can be increased. Furthermore, heat in a logic die can be effectively dissipated by placing an interposer die that has the same size as the logic die between the logic die and memory dies, and thus, heat-dissipation performance and reliability characteristics of the semiconductor package can be increased.

In a method of fabricating a semiconductor package according to an embodiment, a backside power delivery network (BSPDN) layer is formed by applying a wafer-on-wafer (WoW) method, which can increase the productivity and yield of a fabrication process.

While embodiments of the inventive concept have been particularly shown and described, it will be understood by one of ordinary skill in the art that variations in form and detail may be made therein without departing from the spirit and scope of the attached claims.

What is claimed is:

1. A semiconductor package, comprising:
a logic die that includes a backside power delivery network layer;
an interposer die disposed on the logic die;
a plurality of memory dies stacked on the interposer die; and
a mold layer that covers the interposer die and the memory dies,
wherein each of the logic die and the interposer die has a first width.

2. The semiconductor package of claim 1, wherein the logic die comprises:
a first substrate disposed on the backside power delivery network layer; and a frontside interconnection layer disposed on the first substrate, wherein the backside power delivery network layer has a first thickness, the frontside interconnection layer has a second thickness, and the first thickness is greater than the second thickness.

3. The semiconductor package of claim 2, wherein
the backside power delivery network layer comprises:
a first interlayer insulating layer; and
a power line,
wherein the frontside interconnection layer comprises:
a second interlayer insulating layer; and
a signal line, and
wherein the logic die further comprises:
a first penetration via that that penetrates the first substrate and is connected to the power line.

4. The semiconductor package of claim 1, wherein
the memory dies comprise first to fourth memory dies that are sequentially stacked, and
each of the first to fourth memory dies has a third thickness.

5. The semiconductor package of claim 4, wherein each of the first to fourth memory dies further comprises second penetration vias.

6. The semiconductor package of claim 5, further comprising:
third penetration vias that penetrate the interposer die and connect the logic die to the memory dies,
wherein a diameter of each of the third penetration vias is greater than a diameter of each of the second penetration vias, and
a number of the third penetration vias is equal to or greater than a number of the second penetration vias.

7. The semiconductor package of claim 4, wherein
each of the first to fourth memory dies has a second width, and
the first width is greater than the second width.

8. The semiconductor package of claim 4, wherein a sum of thicknesses of the logic die and the interposer die is greater than the third thickness.

9. The semiconductor package of claim 4, wherein
each of the first to third memory dies further comprises upper chip pads disposed on a top surface thereof; and
each of the first to fourth memory dies further comprises lower chip pads disposed on a bottom surface thereof,
the upper chip pads are in contact with corresponding lower chip pads, and
the upper chip pads and the lower chip pads are formed of a same material.

10. The semiconductor package of claim 9, wherein the interposer die further comprises:
first upper conductive pads disposed on a top surface thereof; and
first lower conductive pads disposed on a bottom surface thereof,
wherein the first upper conductive pads are in contact with corresponding lower chip pads of the first memory die, and
the first upper conductive pads and the lower chip pads of the first memory die are formed of a same material.

11. The semiconductor package of claim 10, wherein the logic die further comprises:
second upper conductive pads disposed on a top surface thereof; and
second lower conductive pads disposed on a bottom surface thereof,
wherein the second upper conductive pads are in contact with corresponding first lower conductive pads, and
the second upper conductive pads and the first lower conductive pads are formed of a same material.

12. The semiconductor package of claim 1, wherein the interposer die has a higher thermal conductivity than the logic and memory dies.

13. The semiconductor package of claim 1, wherein the mold layer comprises an oxide material.

14. A semiconductor package, comprising:
a logic die;
an interposer die disposed on the logic die;
a plurality of memory dies stacked on the interposer die;
a mold layer that covers the interposer die and the memory dies; and
a supporting substrate disposed on the memory dies and the mold layer,
wherein the logic die comprises:
a backside power delivery network layer;
a first substrate disposed on the backside power delivery network layer;
a frontside interconnection layer disposed on the first substrate; and
a first penetration via that penetrates the first substrate and is connected to the backside power delivery network layer,
wherein each of the memory dies comprises second penetration vias,
the interposer die comprises third penetration vias that connect the logic die to the memory dies,
the backside power delivery network layer has a first thickness,
the frontside interconnection layer has a second thickness that is less than the first thickness,
each of the memory dies has a third thickness,
a sum of thicknesses of the logic and interposer dies is greater than the third thickness, and
a diameter of the third penetration via is greater than a diameter of the second penetration via,
a number of the third penetration vias is equal to or greater than a number of the second penetration vias,
the mold layer comprises an oxide material,
the supporting substrate comprises silicon,
each of the logic and interposer dies has a first width, and
the interposer die has a higher thermal conductivity than the logic and memory dies.

15. The semiconductor package of claim 14, wherein the logic die further comprises outer connection members disposed on a bottom surface thereof.

16. The semiconductor package of claim 14,
wherein the backside power delivery network layer comprises:
a first interlayer insulating layer; and
a power line,
wherein the frontside interconnection layer comprises:
a second interlayer insulating layer; and
a signal line.

17. The semiconductor package of claim 14,
wherein each of the memory dies further comprises:
upper chip pads disposed on a top surface thereof; and
lower chip pads disposed on a bottom surface thereof,
wherein the interposer die further comprises:
first upper conductive pads disposed on a top surface thereof; and
first lower conductive pads disposed on a bottom surface thereof,
wherein the first upper conductive pads are in contact with corresponding lower chip pads, and
the first upper conductive pads and the lower chip pads are formed of a same material.

18. The semiconductor package of claim 17, wherein the logic die further comprises:
second upper conductive pads disposed on a top surface thereof; and
second lower conductive pads disposed on a bottom surface thereof,
wherein the second upper conductive pads are in contact with corresponding first the lower conductive pads, and
the second upper conductive pads and the first lower conductive pads are formed of a same material.

19. A semiconductor package, comprising:
a package substrate;
an interposer substrate disposed on the package substrate; and
a first semiconductor chip and a second semiconductor chip disposed on the interposer substrate and arranged side by side in a first direction,
wherein the second semiconductor chip comprises:
a logic die that includes a backside power delivery network layer;
an interposer die disposed on the logic die;
a plurality of memory dies stacked on the interposer die; and
a mold layer that covers the interposer die and the memory dies,
wherein the mold layer comprises an oxide material, and
the interposer die has a higher thermal conductivity than the logic memory dies.

20. The semiconductor package of claim 19, wherein the interposer die and the logic die have a same width.
